(19) United States
(12) Patent Application Publication
(10) Pub. No.: US 2009/0160491 A1
(43) Pub. Date: Jun. 25, 2009

(54) INFORMATION PROCESSING APPARATUS

(75) Inventors: Takayuki Ochiai, Ome-Shi (JP); Jun Watanabe, Fussa-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/342,047

(22) Filed: Dec. 22, 2008

(30) Foreign Application Priority Data
Dec. 25, 2007 (JP) 2007-333304

(51) Int. Cl. H03K 5/153

(52) U.S. Cl. 327/80

(57) ABSTRACT

According to one embodiment, an information processing apparatus includes a device connection detection module which monitors a potential of the signal line by disabling the function of a second pull-up resistor by means of a switch circuit and detects that the first or second device has been connected if the potential becomes no higher than a first threshold. The apparatus further includes a device determination module which assesses the potential of the signal line by enabling the function of the second pull-up resistor by means of the switch circuit, and determines, if the potential exceeds a second threshold that is higher than the first threshold, that the first device has been connected, or, if the potential is no higher than the first threshold, that the second device has been connected.

### CROSS-REFERENCE TO RELATED APPLICATIONS

This application is based upon and claims the benefit of priority from Japanese Patent Application No. 2007-333304, filed Dec. 25, 2007, the entire contents of which are incorporated herein by reference.

### BACKGROUND

1. Field

One embodiment of the present invention relates to a device detection process applicable to a computer including an expansion unit, or drive bay, capable of accommodating a specific device, such as a hard disk drive (HDD) or optical disc drive (ODD), selected from a choice of hardware.

2. Description of the Related Art

In recent years, portable, battery-powered notebook computers have become very popular. The latest machines include such features as a wireless communication function or a television receiver function, allowing users to do such things as browsing the Web, sending and receiving e-mail, and watching TV while away from home or the office or while on the road.

Since, in the interests of portability, the size of a notebook computer must be restricted, the addition of extra hardware is often made possible by providing an expansion unit called a drive bay. By means of this drive bay, a user who wishes, say, to add more secondary storage can mount a second HDD, while a user who needs to use CDs or DVDs can mount a ODD. In this way, through the provision of an expansion unit capable of accommodating a specific device selected from a choice of hardware, the computer can be flexibly adapted to the needs of the user without becoming bulky.

Thus, various methods have been proposed for determining which of a selection of devices a user has mounted in the drive bay (refer, for example, to Jpn. Pat. Appln. KOKAI Publication No. 6-64278).

However, the methods proposed so far, in Jpn. Pat. Appln. KOKAI Publication No. 6-64278 and subsequent publications, require the use of circuitry such as multiple signal lines and analog-to-digital converters, making them expensive to implement.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary view showing the external appearance of an information processing apparatus (computer) applicable to the various embodiments of the invention;

FIG. 2 is an exemplary view showing a configuration for executing on a computer a process of device detection of a Digital Versatile Disc drive (DVDD) and an HDD according to a first embodiment of the invention;

FIG. 3 is an exemplary timing chart for explaining the device detection process according to the first embodiment of the invention;

FIG. 4 is an exemplary flowchart for explaining the device detection process according to the first embodiment of the invention;

FIG. 5 is an exemplary view showing a configuration for executing on a computer a process of device detection of a DVDD and an HDD according to a second embodiment of the invention;

FIG. 6 is an exemplary view showing a configuration for executing on a computer a process of device detection of a DVDD and an HDD according to a third embodiment of the invention;

FIG. 7 is an exemplary timing chart for explaining the device detection process according to the third embodiment of the invention; and

FIG. 8 is an exemplary flowchart for explaining the device detection process according to the third embodiment of the invention.

### DETAILED DESCRIPTION

Various embodiments according to the invention will be described hereinafter with reference to the accompanying drawings. In general, according to one embodiment of the invention, an information processing apparatus includes a device connection detection module which monitors a potential of the signal line by disabling the function of a second pull-up resistor by means of a switch circuit and detects that the first or second device has been connected if the potential becomes no higher than a first threshold. The apparatus further includes a device determination module which assesses the potential of the signal line by enabling the function of the second pull-up resistor by means of the switch circuit, and determines, if the potential exceeds a second threshold that is higher than the first threshold, that the first device has been connected, or, if the potential is no higher than the first threshold, that the second device (5b) has been connected.

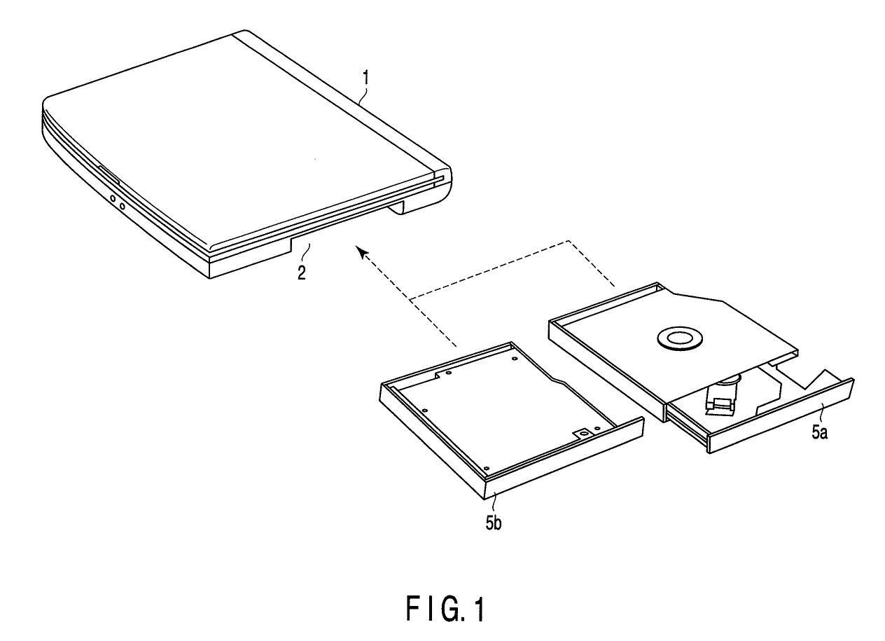

FIG. 1 depicts the external appearance of an information processing apparatus applicable to the embodiments. The information processing apparatus is realized, for example, as a battery-powered notebook computer 1.

As can be seen from FIG. 1, the system unit of the computer 1 occupies a low-profile, box-like housing. A side of this housing is provided with a drive bay 2 that acts as an expansion unit capable of accommodating a DVDD 5a or an HDD 5b. Thus the computer 1 can be configured to exclusively use either the DVDD 5a or the HDD 5b according to the mode of use of the computer 1.

### First Embodiment

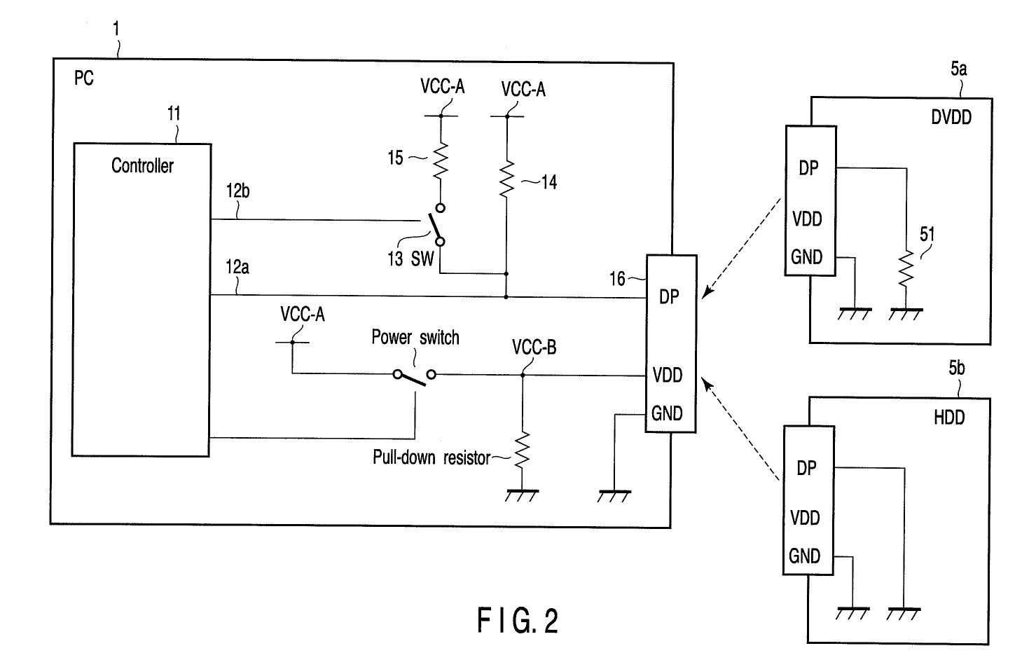

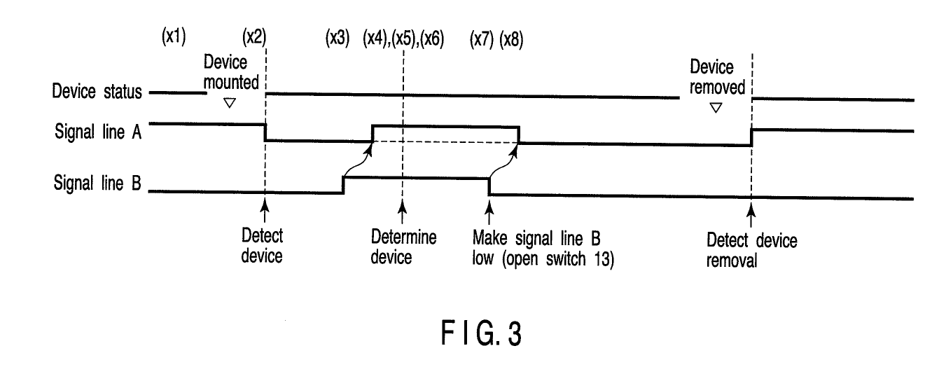

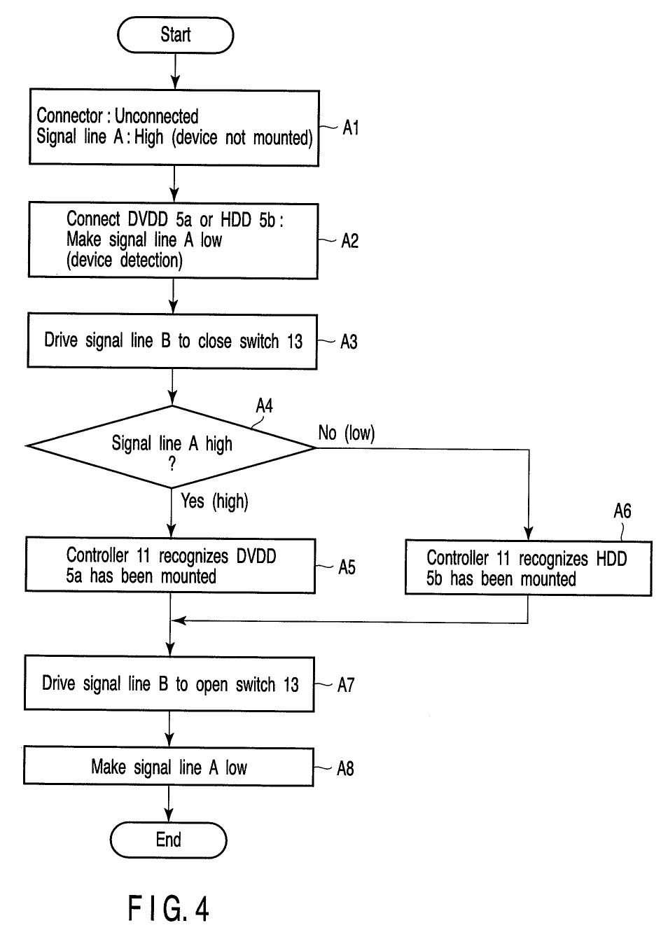

FIG. 2 depicts a configuration for executing on the computer 1 a process of device detection of the DVDD 5a and the HDD 5b according to the first embodiment of the invention. As can be seen from FIG. 2, the DVDD 5a has a Device Present (DP) pin connected to a pull-down resistor 51, while the HDD 5b has a DP pin that is directly grounded. By considering the influence of the DP pin when either the DVDD 5a or the HDD 5b is connected, a process of device detection by the computer 1 (involving a single signal line) according to the first embodiment will be described with reference to the timing chart of FIG. 3 and the flowchart of FIG. 4.

The first embodiment requires that the resistances of first and second pull-up resistors 14 and 15 of the computer 1 and the pull-down resistor 51 of the DVDD 5a be such that the following two criteria are met:

(a) The resistances of the first pull-up resistor 14 of the computer 1 and the pull-down resistor 51 of the DVDD 5a are such that, on connection of the DVDD 5a, the potential of signal line “A” 12a does not exceed the maximum magnitude of potential V_{IL} (potential recognized as logical low) of a controller 11.

(b) The resistance of the second pull-up resistor 15 of the computer 1 is such that the potential of signal line “A” 12a is no lower than potential V_{IH} (potential recognized as logical high) when, on connection of the DVDD 5a, a switch 13 is closed. (The potential of signal line “A” is defined by the potential divider formed by the first and second pull-up resistors 14, 15 of the computer 1 and the pull-down resistor 51 of the DVDD 5a).

The process of device detection begins at time x1 of FIG. 3 (block A1 of FIG. 4), which represents an initial state in which, neither the DVDD 5a nor the HDD 5b being connected to the connector 16, signal line “A” 12a is high (device absent). Since no device is connected, the controller 11 drives signal line “B” 12b to open the switch 13.

When, at time x2 (block A2), the DVDD 5a or the HDD 5b is connected to the connector 16, signal line “A” 12a goes low (device present) and the controller 11 is able to detect that an unidentified device has been mounted.

At time x3 (block A3), the controller 11 drives signal line “B” 12b to close the switch 13, then, at time x4 (block A4), ascertains the state of signal line “A” 12a.

If signal line “A” 12a is high, the controller 11 recognizes that the DVDD 5a has been mounted (time x5, block A5); if signal line “A” 12a is low, the controller 11 recognizes that the HDD 5b has been mounted 16 (time x6, block A6).

When, at time x7 (block A7), determination of the device has been completed, the controller 11 drives signal line “B” 12b to open the switch 13, making signal line “A” 12a low (time x8, block A8).

If, subsequently, the device is disconnected from the connector 16, signal line “A” 12a goes high and the controller 11 is able to detect that the device has been removed.

In this way, according to the configuration of the first embodiment, a single signal line “A” realizes detection of the mounting of a device, determination of the type of device, and detection of the removal of the device.

### Second Embodiment

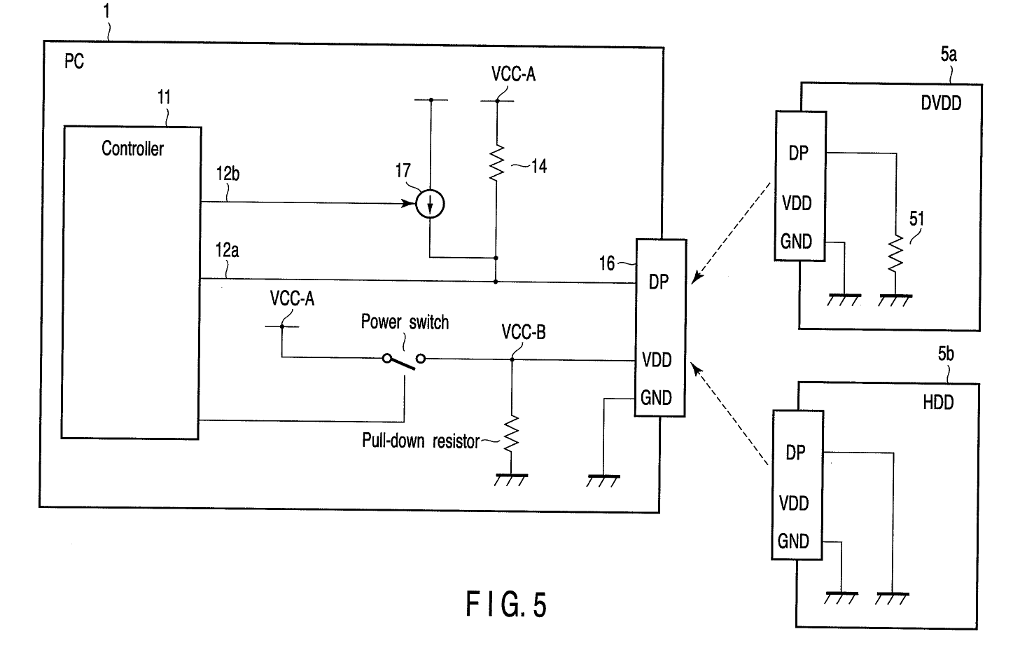

FIG. 5 depicts a configuration for executing on the computer 1 a process of device detection of the DVDD 5a and the HDD 5b according to the second embodiment of the invention. The second embodiment differs from the first in that the first pull-up resistor 15 and the switch 13 of the computer 1, as shown in FIG. 2, are replaced with a constant-current source 17.

In this case, although the potential of signal line “A” 12a rises because of the pull-down resistor 51 of the DVDD 5a, the current of the constant-current source 17 is set so that the potential does not fall below a minimum magnitude of V_{IH} (potential recognized as logical high) and does not exceed the maximum rated potential of the controller 11. Thereby, the device detection process may be carried out in the same way as in the first embodiment.

### Third Embodiment

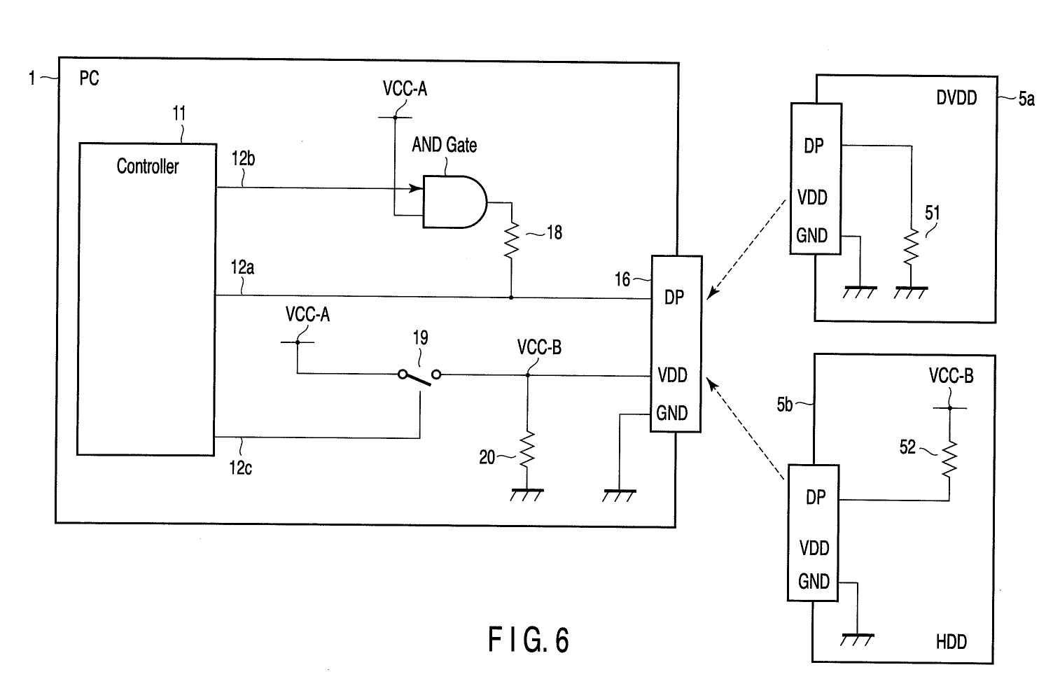

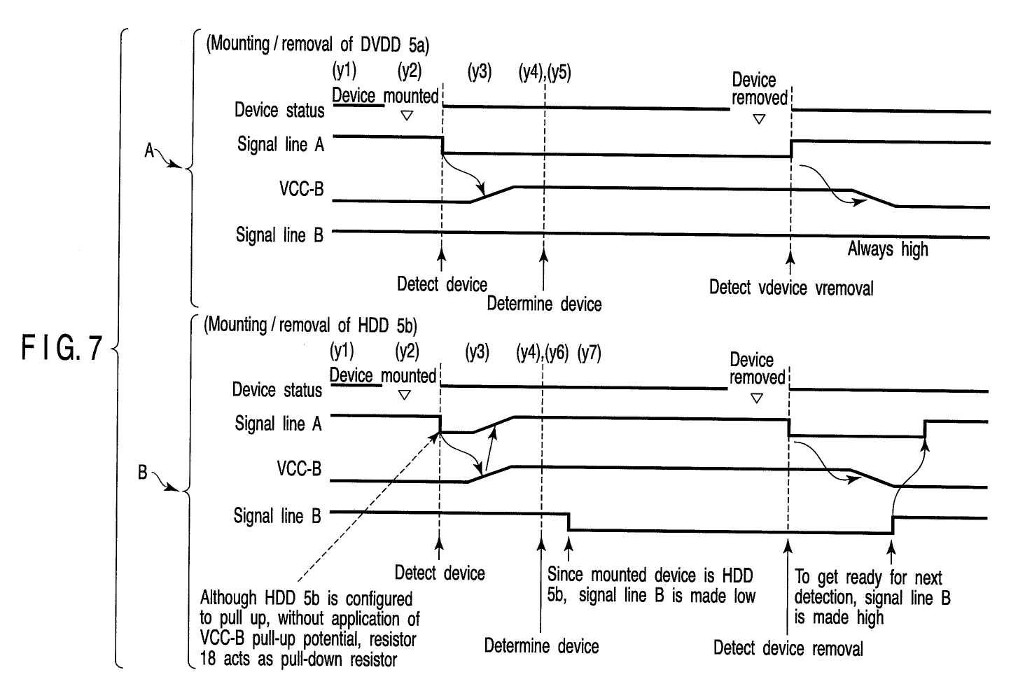

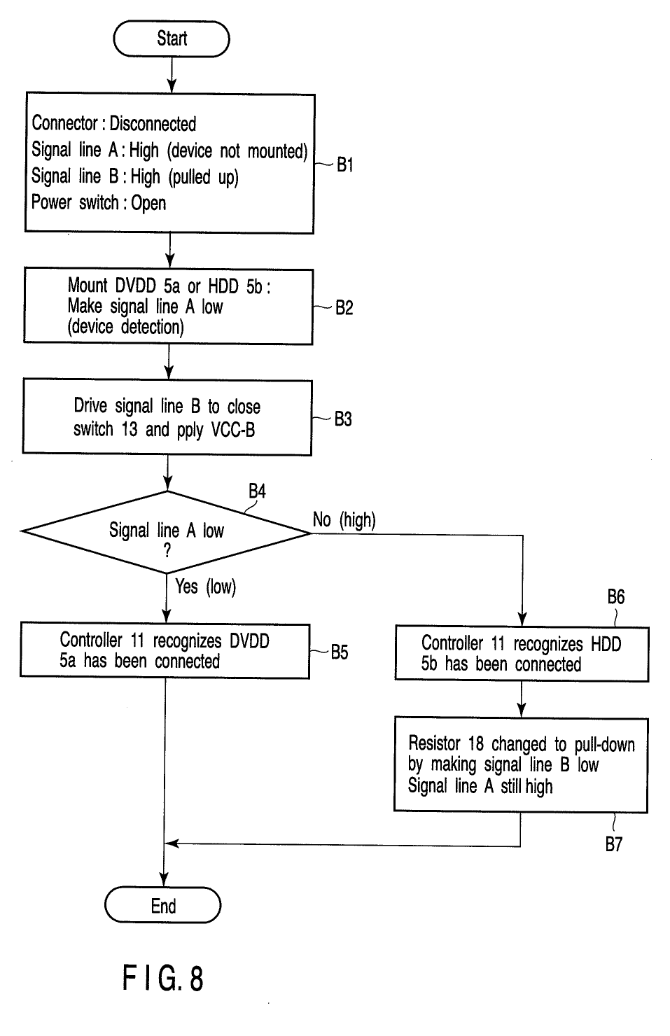

FIG. 6 depicts a configuration for executing on the computer 1 a process of device detection of the DVDD 5a and the HDD 5b according to the third embodiment of the invention. As can be seen from FIG. 6, the DVDD 5a has a DP pin connected to a pull-down resistor 51, while the HDD 5b has a DP pin connected to a pull-up resistor 52 (at potential V_{CC-B}). By considering the influence of the DP pin when either the DVDD 5a or the HDD 5b is connected, a process of device detection by the computer 1 (involving a single signal line) according to the third embodiment will be described with reference to the timing chart of FIG. 7 and the flowchart of FIG. 8.

The third embodiment requires that the resistance of first and second resistors 18, 20 of the computer 1, the pull-down resistor 51 of the DVDD 5a, and the pull-up resistor 52 of the HDD 5b be such that the following four criteria are met:

(a) The resistance of the first resistor 18 of the computer 1 exceeds the greater of the resistance of the pull-down resistor 51 of the DVDD 5a and that of the pull-up resistor 52 of the HDD 5b.

(b) The potential of signal line “A” 12a does not exceed the maximum magnitude of V_{IL} (potential recognized as logical low) of the controller 11 when, on connection of the DVDD 5a, signal line “B” 12b goes high and causes the first resistor 18 of the computer 1 to act as a pull-up resistor.

That is, the resistances satisfy the following condition:

Potential V_{CC-A}×Resistance of pull-down resistor 51 of DVDD 5a/(Resistance of pull-down resistor 51 of DVDD 5a+Resistance of first resistor 18 of computer 1)<V_{IL} (1)

(c) The potential of signal line “B” 12b does not exceed the maximum magnitude of V_{IL} (potential recognized as logical low) of the controller 11 when, on connection of the HDD 5b, the power switch 19 being open so that potential V_{CC-B} is not applied, signal line “B” 12b goes high and causes the first resistor 18 of the computer 1 to act as a pull-up resistor.

That is, the resistances satisfy the following condition:

Potential V_{CC-A}×(Resistance of pull-up resistor 52 of HDD 5b+Resistance of second resistor 20 of computer 1)/(Resistance of pull-up resistor 52 of HDD 5b+Resistance of first resistor 18 of computer 1+Resistance of second resistor 20 of computer 1)<V_{IL} (max) (2)

(d) The potential of signal line “B” 12b does not exceed the minimum magnitude of V_{IH} (potential recognized as logical high) of the controller 11 when, on connection of the HDD 5b, the power switch 19 being closed so that potential V_{CC-B} is applied, signal line “B” 12b goes low and causes the first resistor 18 of computer 1 to act as a pull-down resistor.

That is, the resistances satisfy the following condition:

Potential V_{CC-B}×Resistance of first resistor 18 of computer 1/(Resistance of pull-up resistor 52 of HDD 5b+Resistance of first resistor 18 of computer 1)>V_{IH} (min) (3)

The process of device detection begins at time y1 of FIG. 7 (block B1 of FIG. 8), which represents an initial state in which, neither the DVDD 5a nor the HDD 5b being connected to the connector 16, the controller 11 makes signal line “B” 12b high. Consequently, signal line “A” 12a goes high (device absent).

When, at time y2 (block B2), the DVDD 5a or the HDD 5b is connected to the connector 16, signal line “A” 12a goes low (device present) and the controller 11 is able to detect that an unidentified device has been mounted. (Even in the case of the HDD 5b, although the DP pin is connected to the pull-up resistor 52, since the power switch 19 is open, potential V_{CC-B} is not applied to the pull-up resistor 52, which therefore acts as a pull-down resistor, making signal line “A” 12a low).

At time y3 (block B3), the controller 11 drives signal line “C” 12c to close the power switch 19 and apply potential V_{CC-B}, then, at time y4 (block B4), ascertains the state of signal line “A” 12a.

If signal line “A” 12a is low, the controller 11 recognizes that the DVDD 5a has been mounted (time y5, block B5). Conversely, if signal line “A” 12a is high, the controller 11 recognizes that the HDD 5b has been mounted (time y6, block B6).

At time y7 (block B7), the controller 11 makes signal line “B” 12b low, and the state of signal line “A” remains unchanged (low for the DVDD 5a, high for the HDD 5b).

If, subsequently, the device is disconnected from the connector, signal line “A” 12a goes high for the DVDD 5a and low for the HDD 5b, and the controller 11 is able to detect that the device has been removed. (In the case of the HDD 5b, if the controller 11 had not made signal line “B” 12b low at time y7 [block B7], signal line “A” 12a would have stayed high when the HDD 5b was removed, making detection of removal impossible).

After recognizing the removal of the device, the controller 11 immediately makes signal line “B” 12b high again in preparation for any subsequent mounting of a device.

In this way, according to the configuration of the third embodiment, a single signal line “A” realizes detection of the mounting of a device, determination of the type of device, and detection of the removal of the device.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information processing apparatus comprising:
a connector configured to connect to either a first device in which a first pin of the connector is configured to be connected to a pull-down resistor, or a second device in which the first pin of the connector is configured to be directly grounded;
a first pull-up resistor configured to be connected to the first pin in the connector;
a second pull-up resistor configured to be connected in parallel with the first pull-up resistor;
a switch circuit configured to enable and disable the function of the second pull-up resistor;
a device connection detection module configured to monitor the electrical potential of the first pin of the connector by disabling the function of the second pull-up resistor by means of the switch circuit and to detect that the first or second device has been connected when the electrical potential is equal to or lower than a first threshold voltage; and
a device determination module configured to assess the electrical potential by enabling the function of the second pull-up resistor by means of the switch circuit after the device connection detection module has detected the connection of the first or second device, and configured to determine either that the first device has been connected if the electrical potential exceeds a second threshold voltage higher than the first threshold voltage, or that the second device has been connected if the electrical potential is equal to or lower than the first threshold voltage.

2. The information processing apparatus of claim 1, wherein the resistances of the first and second pull-up resistors relative to the resistance of the pull-down resistor of the first device are set in a manner that the electrical potential is not higher than the first threshold voltage while the first device being connected to information processing apparatus and the switch circuit being open, and that the electrical potential is not lower than the second threshold voltage when the switch circuit is closed.

3. The information processing apparatus of claim 1, further comprising a device removal detection module configured to disable the second pull-up resistor by means of the switch circuit in order to keep the electrical potential lower than the first threshold voltage after the device determination means has completed determination, to monitor the electrical potential, and to detect that the first or second device has been removed if the electrical potential becomes equal to or higher than the second threshold voltage.

4. An information processing apparatus comprising:
a connector configured to connect to either a first device in which a first pin in the connector is configured to be connected to a pull-down resistor, or a second device in which the first pin is configured to be directly grounded;
a first pull-up resistor configured to be connected to the first pin in the connector;
a constant-current source configured to be connected to the first pin in the connector in parallel with the first pull-up resistor;
a switch circuit configured to turn on and off the constant-current source;
a device connection detection module configured to monitor the electrical potential of the first pin in the connector by turning off the constant-current source by means of the switch circuit and to detect that the first or second device has been connected when the electrical potential is equal to or lower than a first threshold voltage; and
a device determination module configured to assess the electrical potential by turning on the constant-current source by means of the switch circuit after the device connection detection means has detected connection of the first or second device, and configured to determine that either the first device has been connected when the electrical potential is equal to or lower than a second threshold voltage that is higher than the first threshold voltage, or that the second device has been connected when the electrical potential is equal to or lower than the first threshold voltage.

5. The information processing apparatus of claim 4, wherein the current of the constant-current source is set in a manner that the electrical potential is not lower than the second threshold voltage while the first device being connected.

6. The information processing apparatus of claim 4, further comprising a device removal detection module configured to turn off the constant-current source by means of the switch circuit in order to make the electrical potential lower than the first threshold voltage after the device determination means has determined, to monitor the electrical potential, and to detect that the first or second device has been removed when the electrical potential is equal to or higher lower than the second threshold voltage.

7. An information processing apparatus comprising:
a connector configured to connect to either a first device in which a first pin in the connector is configured to be connected to a pull-down resistor, or a second device in which the first pin in the connector is configured to be connected to a pull-up resistor;
a resistor configured to be connected to the first pin in the connector;
a switch circuit configured to toggle the function of the resistor between a pull-up function and a pull-down function;
a device connection detection module configured to monitor the electrical potential by causing the resistor to function as a pull-up resistor by means of the switch circuit, and configured to detect that either the first or second device has been connected when the electrical potential is equal to or lower than a first threshold voltage; and
a device determination module configured to supply power to a power line via a first pin in the connector after the device connection detection module has detected connection of the first or second device, configured to assess the electrical potential of the first pin, and configured to determine that either the first device has been connected when the electrical potential is equal to or less than the first threshold voltage, or that the second device has been connected when the electrical potential is equal to or higher than a second threshold voltage that is higher than the first threshold voltage.

8. The information processing apparatus of claim 7, wherein the resistances of the resistor of the information processing apparatus, the pull-down resistor of the first device, and the pull-up resistor of the second device are set so that (1) the resistance of the resistor of the information processing apparatus is greater than both of the resistance of the pull-down resistor of the first device and the resistance of the pull-up resistor of the second device; (2) the electrical potential is equal to or smaller than the first threshold voltage when the first device is connected to the information processing apparatus in a manner that the resistor of the information processing apparatus functions as a pull-up resistor and no power is supplied via the power line; (3) the electrical potential does not exceed the first threshold voltage when the second device is connected to the information processing apparatus in a manner that the resistor of the information processing apparatus functions as a pull-up resistor and no power is supplied via the power line; and (4) the electrical potential is equal to or higher than the second threshold voltage when power supply through the power line is started at connecting the second device to the information processing apparatus comprising the resistor configured to function as the pull-down resistor.

9. The information processing apparatus of claim 7, further comprising a device removal detection module configured to cause the resistor to function as a pull-down resistor by switching the switch circuit in order to set the electrical potential higher than the second threshold voltage and to monitor the electrical potential when the device determination module has determined that the second device has been connected, configured to detect removal of the second device when the electrical potential is equal to or lower than the first threshold voltage, configured to set the electrical potential lower than the first threshold voltage by keeping the resistor functioning as a pull-up resistor by the switch circuit and to monitor the electrical potential when the device determination module has determined that the first device has been connected, and configured to detect removal of the first device when the electrical potential is equal to or higher than the second threshold voltage.
